(19) United States
(12) Patent Application Publication
(10) Pub. No.: US 2025/0328417 A1
(43) Pub. Date: Oct. 23, 2025

(54) DATA STORAGE DEVICE

(71) Applicant: SK hynix Inc., Gyeonggi-do (KR)

(72) Inventors: Chang Hoon LEE, Gyeonggi-do (KR); Seung Yeol LEE, Gyeonggi-do (KR)

(21) Appl. No.: 19/057,990

(22) Filed: Feb. 20, 2025

(30) Foreign Application Priority Data
Apr. 18, 2024 (KR) 10-2024-0052073

(51) Int. Cl. G06F 11/10

(52) U.S. Cl. CPC G06F 11/1044

(57) ABSTRACT

Various embodiments of the present disclosure relate to a memory device, and the memory device may comprise a plurality of bank groups, each bank group including a plurality of banks, each bank including two sub-banks, each sub-bank including a plurality of memory cells, and a peripheral circuit configured to receive a control signal and a data chunk from an external device, and store the data chunk to be distributed in at least two or more sub-banks selected from among sub-banks included in the plurality of bank groups.

### CROSS REFERENCE TO RELATED APPLICATION

The present application claims priority to Korean Patent Application No. 10-2024-0052073, filed on Apr. 18, 2024, the entire contents of which are incorporated herein for all purposes by this reference.

### FIELD

Embodiments of the present disclosure relate to a data storage device capable of distributing a burst defect.

### BACKGROUND

A memory device may store data based on a command from an external device and provide the stored data to the external device.

The memory device includes a plurality of memory cells that can store data. When an error occurs while storing data in the memory cells or reading data from the memory cells, data with an error is output and transferred to the external device.

When the external device uses the data with an error, a system error of the external device may be induced. To prevent the system error, the external device may use an error correction code that may detect and correct the error in the data read from the memory device.

Theoretically, only the parity bits need to be increased to detect and correct more errors more accurately. This increase may make the structure heavy and design difficult and cause many issues such as lowering processing speed, and data transmission efficiency. Also, in the memory device, there is a concern of reducing the available capacity of the memory device as the area for storing parity bits increases.

An error correction code may sufficiently recover the original data even with small parity bits when the number of errors occurring within a data chunk is small. Therefore, it needs to lower the possibility of many errors occurring simultaneously within one data chunk.

### SUMMARY

Various embodiments of the present disclosure provide a memory device capable of distributing, into a plurality of data chunks, error bits which are generated when a defect causing a burst error of the memory device occurs.

Various embodiments of the present disclosure provide a memory device capable of reducing the number of error bits generated in one data chunk when a burst error occurs due to a failure in a sub-word line driver in the memory device.

Technical concerns to be solved by the embodiments of the present disclosure are not limited to the technical concerns mentioned above, and other unmentioned technical concerns can be clearly understood by those skilled in the art from the description below.

According to various embodiments of the present disclosure, a memory device may comprise a plurality of bank groups, each bank group including a plurality of banks, each bank including two sub-banks, each sub-bank including a plurality of memory cells, and a peripheral circuit configured to receive a first control signal and a data chunk from an external device, and store the data chunk to be distributed in at least two or more sub-banks selected from among sub-banks included in the plurality of bank groups.

The peripheral circuit may be configured to select one bank from among banks of the plurality of bank groups, based on the first control signal, and store the data chunk to be distributed in two sub-banks in the selected bank.

The first control signal may comprise a first address, and the peripheral circuit may be further configured to select a first bank based on part of the first address, and store half of the data chunk in each of the two sub-banks of the selected first bank based on a remaining part of the first address.

The peripheral circuit may be further configured to receive a second control signal from the external device, and read the data chunk stored from two sub-banks in the selected bank based on the second control signal.

The peripheral circuit may be configured to select two banks from among banks of the plurality of bank groups, based on the first control signal, and store the data chunk to be distributed in four sub-banks in the selected two banks. The selected two banks may be included in the same bank group.

The first control signal may include a second address, and the peripheral circuit may be further configured to select a first bank group based on a first part of the second address, select a first bank and a second bank among the plurality of banks in the first bank group based on a second part of the second address, and store a quarter of the data chunk in each of two sub-banks of the first bank and two sub-banks of the second bank based on a remaining part of the second address.

The peripheral circuit may be configured to select one bank group from among the plurality of bank groups based on the first control signal, and store the data chunk to be distributed in eight sub-banks in four banks in the selected bank group.

The first control signal may include a third address, and the peripheral circuit may be configured to select a first bank group based on a first part of the third address, store one-eighth of the data chunk in each of two sub-banks in four banks in the first bank group based on a second part of the third address.

According to various embodiments of the present disclosure, a data storage device may comprise a plurality of first memory devices for storing a data chunk, a second memory device for storing an error correction code generated based on the data chunk and a peripheral circuit configured to receive a first control signal from an external device and control the plurality of first memory devices and the second memory device. Each of the plurality of first memory devices and the second memory device may include a plurality of bank groups, each bank group including a plurality of banks, each bank including two sub-banks, each sub-bank including a plurality of memory cells. The peripheral circuit may be configured to store the data chunk and the error correction code to be distributed in at least two or more sub-banks selected from among sub-banks included in the plurality of bank groups in each of the plurality of first memory devices and the second memory device.

The peripheral circuit may be further configured to select one bank from among banks of the plurality of bank groups in each of the plurality of first memory devices and the second memory device, based on the first control signal, and store the data chunk and the error correction code to be distributed in two sub-banks in the selected bank.

The first control signal may include a first address, and the peripheral circuit may be further configured to select a first bank from each of the plurality of first memory devices and the second memory device based on a part of the first address, and store the data chunk and the error correction code in two sub-banks of the selected first bank based on a remaining part of the first address.

The peripheral circuit may be further configured to receive a control signal from the external device, and read the data chunk and the error correction code stored from two sub-banks in the selected bank based on the second control signal.

The peripheral circuit may be further configured to select two banks from among banks of the plurality of bank groups in each of the plurality of first memory devices and the second memory device based on the first control signal, and store the data chunk and the error correction code to be distributed in four sub-banks in the selected two banks.

The peripheral circuit may be further configured to select one bank group among the plurality of bank groups from each of the plurality of first memory devices and the second memory device based on the control signal, and store the data chunk and the error correction code to be distributed in eight sub-banks of four banks in the selected bank group.

The number of the plurality of first memory devices may be 4.

A size of the data chunk may be calculated by multiplying a burst length (N) and 32 bits, and a size of the error correction code may be calculated by multiplying a burst length (N) and 8 bits. Each of the plurality of first memory devices and the second memory device may be configured to simultaneously receive or output eight bits.

The peripheral circuit may sequentially receive 40-bit data signals from the external device for as many times as a number corresponding to the burst length (N). Further, the peripheral circuit may sequentially transfer 8 bits at a time to each of the plurality of first memory devices and the second memory device.

### BRIEF DESCRIPTION OF THE DRAWINGS

FIG. 1 is a block diagram showing a memory system according to an embodiment of the present disclosure.

FIG. 2 is a block diagram showing a first memory device shown in FIG. 1.

FIG. 3 is a view showing a bank group and banks according to an embodiment of the present disclosure.

FIG. 4 is a view showing a left sub-bank or a right sub-bank within a bank according to an embodiment of the present disclosure.

FIG. 5 is a view showing data read from a bank.

FIG. 6 is a view partially showing the left sub-bank and the right sub-bank of a bank for the purpose of description.

FIG. 7 is a view showing an output result of data read according to one type of a method that has been proposed.

FIG. 8 is a view showing data stored in each memory cell according to an embodiment of a method proposed in the present disclosure.

FIG. 9 is a view showing an output result of data read according to embodiments of the present disclosure.

FIG. 10 is a view showing data stored in each memory cell according to a method proposed in a second embodiment of the present disclosure.

FIG. 11 is a view showing an example of an output result in the case of reading according to a method proposed in a second embodiment of the present disclosure.

### DETAILED DESCRIPTION

Hereinafter, embodiments of the present disclosure will be described in detail with reference to the accompanying drawings so that those skilled in the art may easily understand. However, the embodiments of the present disclosure may be implemented in several different forms and are not limited to the embodiments described herein. In addition, to clearly describe the embodiments in the drawings, parts that are not related to the description are omitted, and similar reference numerals are given to similar parts throughout the specification.

Throughout the specification, when a part is said to “include” a certain component, this means that it may further include other components rather than excluding other components unless specifically stated otherwise.

As the terms used in the description of the embodiments of the present disclosure, general terms widely used are selected as much as possible considering their functions. However, this may vary according to the intention of those skilled in the art, precedents, emergence of new technologies, or the like. In addition, there are terms randomly selected by the applicant in a specific case, and in this case, their meaning will be described in detail in the description of corresponding embodiments. Therefore, the terms used in the embodiments should not be defined simply by the names of the terms but should be defined based on the meaning of the terms and the overall content of the embodiments.

In an embodiment of the present disclosure, although terms including ordinal numbers such as first, second, and the like may be used to describe various components, the components are not limited by the terms. The terms are used only to distinguish one component from the others. For example, a first component may be named a second component, and similarly, a second component may also be named a first component without departing from the scope of the present disclosure. The term “and/or” includes a combination of a plurality of related items stated herein or one among a plurality of related items stated herein.

In addition, in an embodiment of the present disclosure, singular expressions include plural expressions unless the context clearly dictates otherwise.

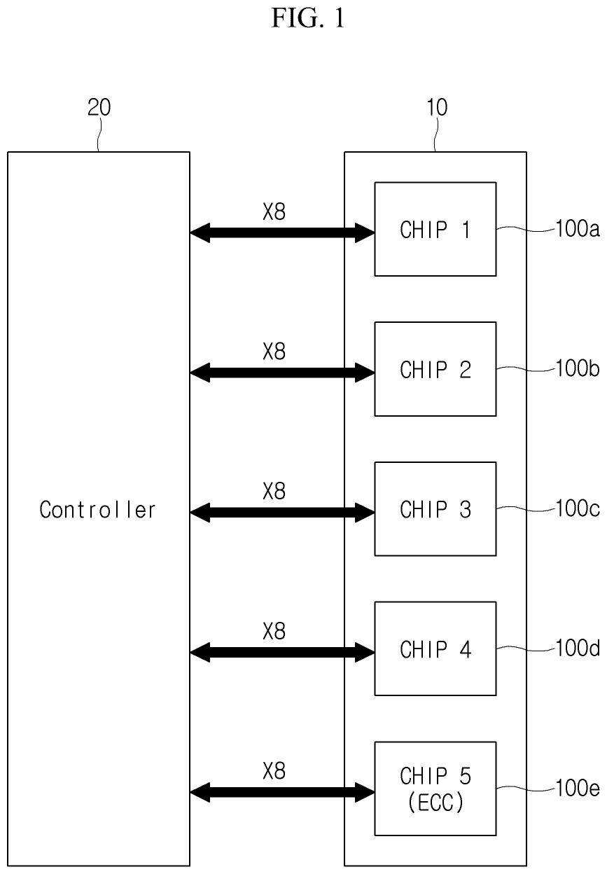

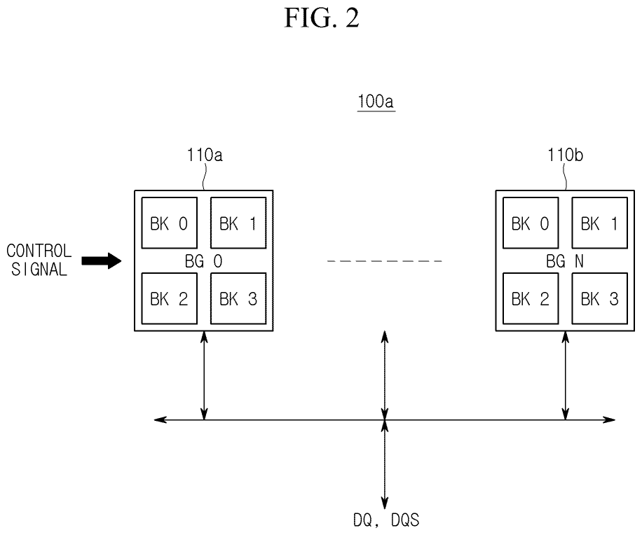

FIG. 1 is a block diagram showing a memory system according to an embodiment of the present disclosure, and FIG. 2 is a block diagram showing a first memory device 100a shown in FIG. 1.

Referring to FIG. 1, the memory system may include a data storage device 10 and a controller 20.

The data storage device 10 may include a plurality of memory devices 100a to 100e. Although the data storage device 10 is shown to include five memory devices 100a to 100e in FIG. 1, however, the present disclosure is not limited thereto, and various numbers of memory devices may be included in the data storage device 10 as needed.

The memory devices 100a to 100e may communicate with the controller 20 through corresponding connectors. In the illustrated embodiment of FIG. 2, the memory devices 100a to 100e may communicate with the controller 20, using data signals DQ, data strobe signals DQS, and control signals.

In an embodiment, the controller 20 may be included in an external host device. In this embodiment, the memory devices 100a to 100e may simultaneously receive data signals DQ and store the received data signals DQ in response to a request from the external host device.

Each of the memory devices 100a to 100e may be implemented with double data rate 5 (DDR5) synchronous dynamic random access memory (SDRAM). The memory devices 100a to 100e may communicate with the controller 20 as is defined in the Joint Electron Device Engineering Council (JEDEC) standards of Dual In-Line Memory Module (DIMM), more specifically, DDR5 SDRAM DIMM.

The memory devices 100a to 100e may sequentially receive or sequentially output the data signals DQ for as many times as a number corresponding to the burst length BL. For example, according to the standards of DDR5 SDRAM DIMM, the burst length (BL) may be 16.

In the illustrated embodiment of FIG. 1, the first to fourth memory devices 100a to 100d may be memory devices for storing data, while the fifth memory device 100e may be a memory device for storing data for error correction. The controller 20 may control the operation of the memory devices 100a to 100e in the data storage device 10 to store data in the first to fourth memory devices 100a to 100d and store an error correction code (ECC) in the fifth memory device 100e.

In some embodiments, the control signal provided by the controller 20 to the data storage device 10 is simultaneously transmitted to the first to fifth memory devices 100a to 100e inside the data storage device 10. The first to fifth memory devices 100a to 100e may be controlled to perform the same operation at the same time based on the control signal. Further, the controller and each of the first to fifth memory devices 100a to 100e use 8 bits data lines (X8) to transmit data for storing or reading.

For example, the second to fifth memory devices 100b to 100e may also have a structure the same as that of the first memory device 100a, and operate in the same manner.

Referring to FIGS. 1 and 2, the first memory device 100a may include a plurality of bank groups BG0 110a to BGN 110b. According to the standard specifications of DDR5 SDRAM DIMM, a memory device may include up to eight bank groups. Each of the bank groups 110a and 110b (collectively referred to as a bank group 110) may include first to fourth banks BK0, BK1, BK2, and BK3. All bank groups 110 in the memory device may have the same structure including the first to fourth banks BK0, BK1, BK2, and BK3, and operate in the same manner. Each bank BK0, BK1, BK2, or BK3 may include memory cells. The memory cells may be used to store data or an error correction code transferred from the controller 20.

The memory device 100a may further include a peripheral circuit capable of receiving a control signal including a command CMD and an address ADDR, data signals DQ, and data strobe signals DQS, and transferring the data signals DQ to a desired bank based on the control signal.

The peripheral circuit may control a selected bank to perform an operation indicated by the command, for example, a write operation or a read operation, on the memory cells indicated by the address ADDR among the memory cells of the selected bank.

The peripheral circuit may communicate data signals DQ and data strobe signals DQS with the controller 20. The data strobe signals DQS may be used to transfer timings for latching the data signals DQ.

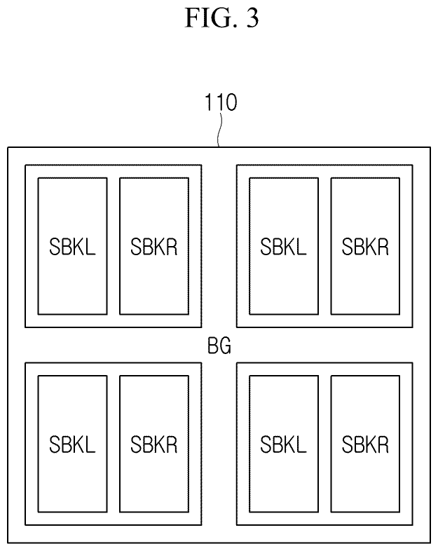

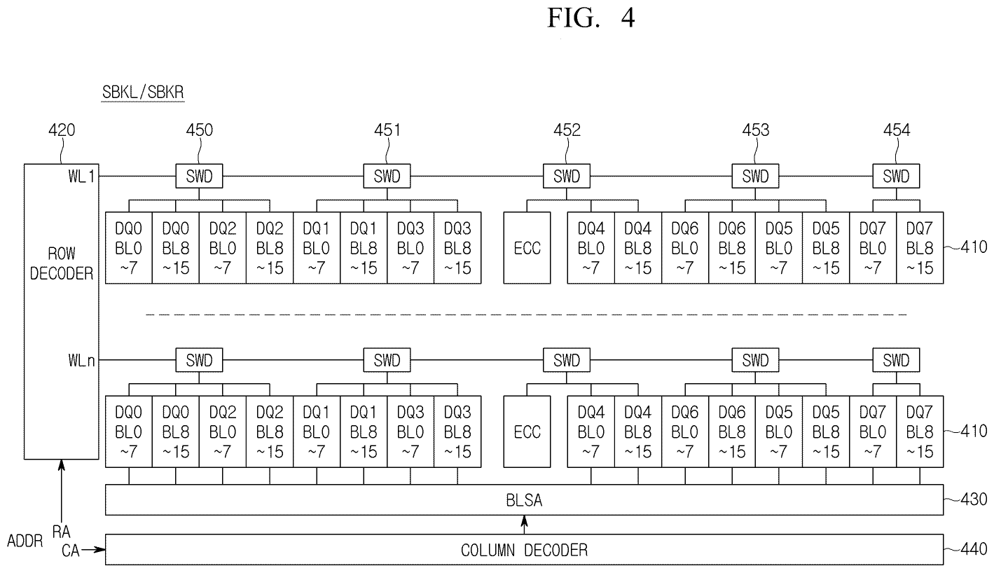

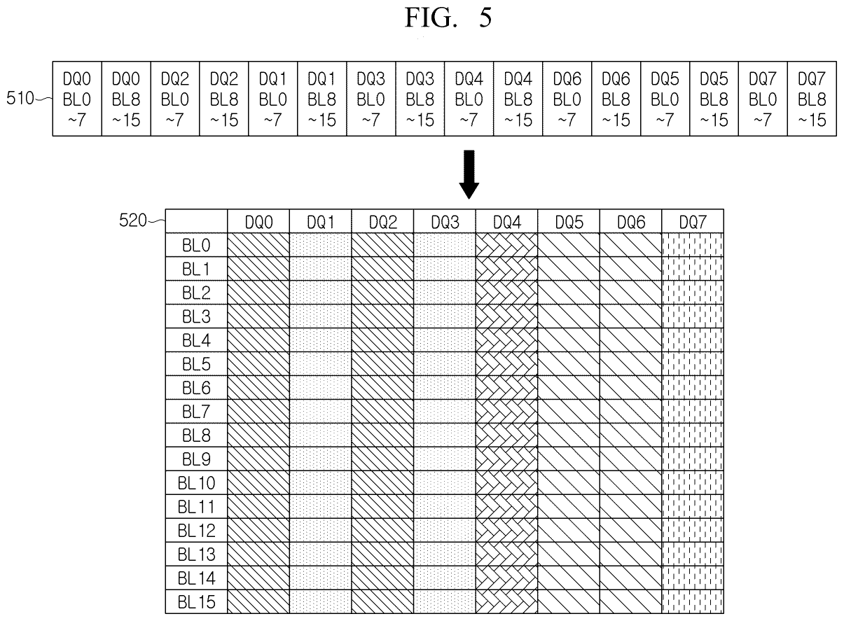

FIG. 3 is a view showing a bank group and banks according to an embodiment of the present disclosure, FIG. 4 is a view showing a left sub-bank (SBKL) or a right sub-bank (SBKR) within a bank according to an embodiment of the present disclosure, and FIG. 5 is a view showing data read from a bank.

For example, the bank group 110 is one among the plurality of bank groups 110a and 110b shown in FIG. 2. In addition, referring to FIG. 3, the banks BK0, BK1, BK2, and BK3 in the bank group 110 may include left sub-banks SBKL and right sub-banks SBKR. The left sub-banks SBKL and the right sub-banks SBKR may have the same structure as shown in FIG. 4.

Referring to FIGS. 1 to 4, each of the left sub-banks SBKL or the right sub-banks SBKR may include memory cell arrays 410, a row decoder 420, a bit line sense amplifier (BLSA) 430, a column decoder 440, and sub-word line decoders SWD 450, 451, 452, 453, and 454.

The memory cell array 410 may include memory cells arranged along the row and column directions. The memory cell array 410 may be a component that actually stores data therein.

The row decoder 420 may be connected to the rows of the memory cells through word lines WL1 to WLn, where n is a positive integer greater than 1. The row decoder 420 may receive a row address RA in the address ADDR and select one of first to n-th word lines WL1 to WLn in response to the row address RA. For example, the row decoder 420 may apply a voltage (e.g., positive voltage) for activating the selected word line.

The bit line sense amplifier 430 may be connected to the columns of the memory cells through bit lines. The bit line sense amplifier 430 may be connected to bit lines different from each other. The bit line sense amplifier 430 may apply voltages to the bit lines and/or sense voltages of the bit lines. By adjusting or sensing the voltages of the bit lines, the bit line sense amplifier 430 may perform a write operation or a read operation on the memory cells of a selected row.

The column decoder 440 may receive a column address CA in the address ADDR. The column decoder 440 may electrically connect some of the bit lines to the peripheral circuit in response to the column address CA.

In the illustrated embodiment of FIG. 5, when the first word line WL1 is selected by the row decoder 420, the sub-word line decoders 450, 451, 452, 453, and 454 connected to the first word line WL1 may be activated and output data 510 of memory cells. The column decoder 440 may sequentially select burst data bits DQ0 to DQ7 of BL0 to BL15 and output data read from corresponding memory cells so that the data chunk 520 corresponding to the burst length (e.g., 16) may be output. In the embodiment of FIG. 5, the same pattern may represent data output from memory cells managed by the same sub-word line decoder. That is, the first data bit DQ0 and the third data bit DQ2 may be data activated by the first sub-word line decoder 450, the second data bit DQ1 and the fourth data bit DQ3 may be data activated by the second sub-word line decoder 451, the fifth data bit DQ4 may be data activated by the third sub-word line decoder 452, the sixth data bit DQ5 and the seventh data bit DQ6 may be data activated by the fourth sub-word line decoder 453, and the eighth data bit DQ7 may be data activated by the fifth sub-word line decoder 454.

However, when the first sub-word line decoder 450 malfunctions, an error may occur in all 32 data bits of the first data bit DQ0 and the third data bit DQ2 of all bursts BL0 to BL15. In this example, even when an error does not occur in other chips among the chips shown in FIG. 1, an error of at least 32 bits occurs in a data chunk configured of 512(=16*8*4) data bits and 128(=16*8) error correction code bits, and thus error correction for the data chunk may not be possible.

As such, the number of bits in which an error occurs is increased when one sub-word line decoder malfunctions, and the error correction may be incapable. In order to resolve the incapability of correcting the error, embodiments of the present disclosure provide a method of reducing the number of bits managed by each sub-word line decoder in one data chunk by half.

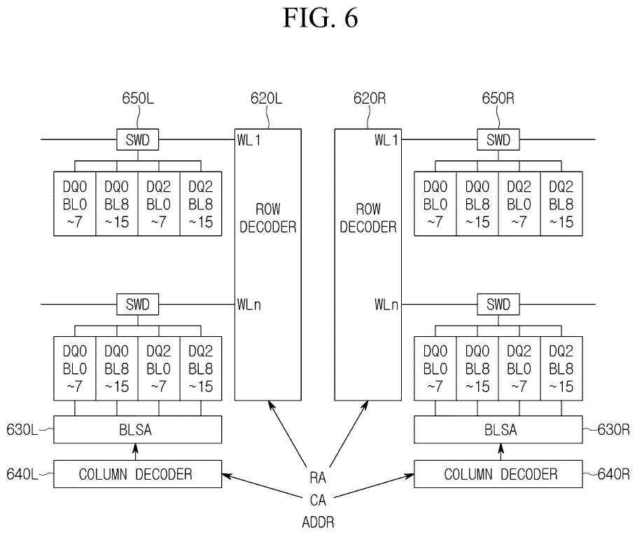

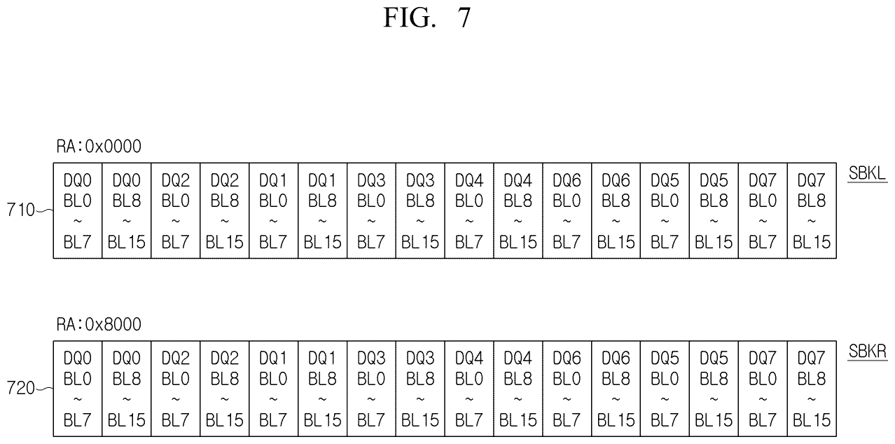

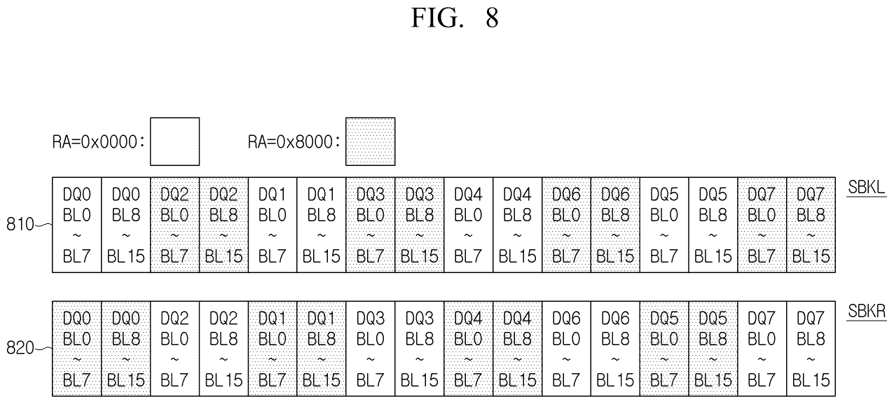

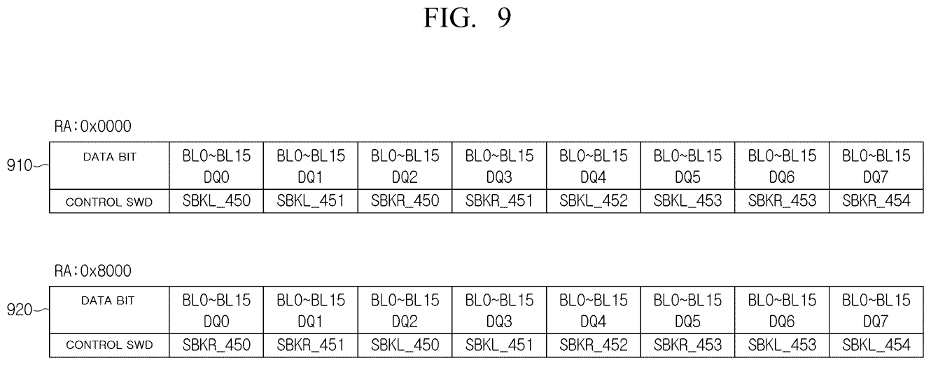

FIG. 6 is a view partially showing the left sub-bank and the right sub-bank of a bank. FIG. 7 is a view showing an output result of data read according to one type of a method that has been proposed. FIG. 8 is a view showing data stored in each memory cell according to embodiments of the present disclosure. FIG. 9 is a view showing an output result of data read according to embodiments of the present disclosure.

Although FIG. 6 shows only a sub-word line driver that controls the first data bit DQ0 and the third data bit DQ2, other sub-word lines may also operate in the same manner.

Each of the word lines WL1 to WLn of the bank shown in FIG. 6 may be selected by the row address RA. The sub-word line decoders 650L and 650R may activate the memory cells for read or write operations based on the row address RA. For example, the sub-word line decoder 650L connected to the first word line WL1 of the left sub-bank SBKL may activate the memory cells managed when the row address RA is 0×0000 as shown in FIG. 7. In another embodiment, the sub-word line decoder 650R connected to the first word line WL1 of the right sub bank SBKR may activate the memory cells managed when the row address RA is 0×8000 as shown in FIG. 7. That is, the left sub-bank SBKL may operate or the right sub-bank SBKR may be activated by the most significant bit (MSB) of the 16-bit row address. In one type of method that has been proposed, either the left sub-bank SBKL or the right sub-bank SBKR is selected according to whether the most significant bit RA15 has a value of 0 or 1. When the left sub-bank SBKL is selected according thereto, a word line is selected by the lower row address RA14 to RA0, and the sub-word line decoder SWD connected to the selected word line activates memory cells to read data from the memory cells. For example, when the row address RA is 0×0000, data of the first output 710 of FIG. 7 may be read from the memory cells controlled by the sub-word line decoder 650L of FIG. 6 connected to the first word line WL1 of the left sub-bank SBKL. When the row address RA is 0×8000, data of the second output 720 of FIG. 7 may be read from the memory cells controlled by the sub-word line decoder 650R of FIG. 6 connected to the first word line WL1 of the right sub-bank SBKR.

Unlike the one type of method that has been proposed, a method of reducing the number of bits controlled by one sub-word line decoder SWD by half in a data chunk of 16-byte long is proposed as a first embodiment. Accordingly, although an error occurs in a sub-word line decoder, the number of error bits occurring in one data chunk may be reduced by half compared to the one type of method that has been proposed.

To this end, from selecting one among the left sub-bank SBKL and the right sub-bank SBKR using the most significant bit RA15 of the row address RA, the scheme may be changed to simultaneously select the left sub-bank SBKL and the right sub-bank SBKR in the bank, and control only 16 memory cells to store or read data in or from one data chunk among 32 memory cells by each sub-word line decoder based on the most significant bit RA15 of the row address RA.

Referring to FIGS. 6 and 8, the first sub-word line decoder 450 of the left sub bank SBKL may control to store, in the memory cells, the first data bit DQ0 of all bursts BL0 to BL15 of the first data chunk, or the third data bit DQ2 of all bursts BL0 to BL15 of the second data chunk. The first data bit DQ0 of all bursts BL0 to BL15 of the first data chunk corresponds to an address in which the most significant bit RA15 of the row address RA is 0. The third data bit DQ2 of all bursts BL0 to BL15 of the second data chunk corresponds to an address in which the most significant bit RA15 of the row address RA is 1.

Similarly, the second sub-word line decoder 451 of the left sub bank SBKL may control to store, in the memory cells, the second data bit DQ1 of all bursts BL0 to BL15 of the first data chunk, or the fourth data bit DQ3 of all bursts BL0 to BL15 of the second data chunk. The second data bit DQ1 of all bursts BL0 to BL15 of the first data chunk corresponds to an address in which the most significant bit RA15 of the row address RA is 0. The fourth data bit DQ3 of all bursts BL0 to BL15 of the second data chunk corresponds to an address in which the most significant bit RA15 of the row address RA is 1.

As the number of controlled memory cells may be limited to 16, the third sub-word line decoder 452 of the left sub bank SBKL may control to store, in the memory cells, the fifth data bit DQ4 of all bursts BL0 to BL15 of the first data chunk, which corresponds to an address in which the most significant bit RA15 of the row address RA is 0.

The fourth sub-word line decoder 453 of the left sub bank SBKL may control to store, in the memory cells, the sixth data bit DQ5 of all bursts BL0 to BL15 of the first data chunk, or the seventh data bit DQ6 of all bursts BL0 to BL15 of the second data chunk. The sixth data bit DQ5 of all bursts BL0 to BL15 of the first data chunk corresponds to an address in which the most significant bit RA15 of the row address RA is 0. The seventh data bit DQ6 of all bursts BL0 to BL15 of the second data chunk corresponds to an address in which the most significant bit RA15 of the row address RA is 1.

As the number of controlled memory cells may be limited to 16, the fifth sub-word line decoder 454 of the left sub bank SBKL may control to store, in the memory cells, the eighth data bit DQ7 of all bursts BL0 to BL15 of the second data chunk, of which the most significant bit RA15 of the row address RA corresponds to 1.

The first sub-word line decoder 450 of the right sub bank SBKR may control to store, in the memory cells, the third data bit DQ2 of all bursts BL0 to BL15 of the first data chunk, or the first data bit DQ0 of all bursts BL0 to BL15 of the second data chunk. The third data bit DQ2 of all bursts BL0 to BL15 of the first data chunk corresponds to an address in which the most significant bit RA15 of the row address RA is 0. The first data bit DQ0 of all bursts BL0 to BL15 of the second data chunk corresponds to an address in which the most significant bit RA15 of the row address RA is 1.

Similarly, the second sub-word line decoder 451 of the right sub bank SBKR may control to store, in the memory cells, the fourth data bit DQ3 of all bursts BL0 to BL15 of the first data chunk, or the second data bit DQ1 of all bursts BL0 to BL15 of the second data chunk. The fourth data bit DQ3 of all bursts BL0 to BL15 of the first data chunk corresponds to an address in which the most significant bit RA15 of the row address RA is 0. The second data bit DQ1 of all bursts BL0 to BL15 of the second data chunk corresponds to an address in which the most significant bit RA15 of the row address RA is 1.

As the number of controlled memory cells may be limited to 16, the third sub-word line decoder 452 of the right sub bank SBKR may control to store, in the memory cells, the fifth data bit DQ4 of all bursts BL0 to BL15 of the second data chunk, of which the most significant bit RA15 of the row address RA corresponds to 1.

The fourth sub-word line decoder 453 of the right sub bank SBKR may control to store, in the memory cells, the seventh data bit DQ6 of all bursts BL0 to BL15 of the first data chunk, or the sixth data bit DQ5 of all bursts BL0 to BL15 of the second data chunk. The seventh data bit DQ6 of all bursts BL0 to BL15 of the first data chunk corresponds to an address in which the most significant bit RA15 of the row address RA is 0. The sixth data bit DQ5 of all bursts BL0 to BL15 of the second data chunk corresponds to an address in which the most significant bit RA15 of the row address RA is 1.

As the number of controlled memory cells may be limited to 16, the fifth sub-word line decoder 454 of the right sub bank SBKR may control to store, in the memory cells, the eighth data bit DQ7 of all bursts BL0 to BL15 of the first data chunk, which corresponds to an address in which the most significant bit RA15 of the row address RA is 0.

Accordingly, the first data bit DQ0, the second data bit DQ1, the fifth data bit DQ4, and the sixth data bit DQ5 of all bursts BL0 to BL15 of the first data chunk corresponding to an address where the most significant bit RA15 of the row address RA is 0 may be stored in the left sub bank SBKL 810. The third data bit DQ2, the fourth data bit DQ3, the seventh data bit DQ6, and the eighth data bit DQ7 of all bursts BL0 to BL15 of the first data chunk corresponding to an address where the most significant bit RA15 of the row address RA is 0 may be stored in the right sub bank SBKR 820. In addition, the first data bit DQ0, the second data bit DQ1, the fifth data bit DQ4, and the sixth data bit DQ5 of all bursts BL0 to BL15 of the second data chunk corresponding to an address where the most significant bit RA15 of the row address RA is 1 may be stored in the right sub bank SBKR 820. The third data bit DQ2, the fourth data bit DQ3, the seventh data bit DQ6, and the eighth data bit DQ7 of all bursts BL0 to BL15 of the second data chunk corresponding to an address where the most significant bit RA15 of the row address RA is 1 may be stored in the left sub bank SBKL 810.

Describing from the viewpoint of reading a data chunk, as shown in 910 of FIG. 9, the first data chunk corresponding to an address where the most significant bit RA15 of the row address RA is 0 may be configured of the first data bit DQ0 of each of the bursts BL0 to BL15, the second data bit DQ1 of each of the bursts BL0 to BL15, the third data bit DQ2 of each of the bursts BL0 to BL15, the fourth data bit DQ3 of each of the bursts BL0 to BL15, the fifth data bit DQ4 of each of the bursts BL0 to BL15, the sixth data bit DQ5 of each of the bursts BL0 to BL15, the seventh data bit DQ6 of each of the bursts BL0 to BL15, and the eighth data bit DQ7 of each of the bursts BL0 to BL15. The first data bit DQ0 of each of the bursts BL0 to BL15 may be output based on the control of the first sub-word line decoder 450 of the left sub bank SBKL. The second data bit DQ1 of each of the bursts BL0 to BL15 may be output based on the control of the second sub-word line decoder 451 of the left sub bank SBKL. The third data bit DQ2 of each of the bursts BL0 to BL15 may be output based on the control of the first sub-word line decoder 450 of the right sub bank SBKR. The fourth data bit DQ3 of each of the bursts BL0 to BL15 may be output based on the control of the second sub-word line decoder 451 of the right sub bank SBKR. The fifth data bit DQ4 of each of the bursts BL0 to BL15 may be output based on the control of the third sub-word line decoder 452 of the left sub bank SBKL. The sixth data bit DQ5 of each of the bursts BL0 to BL15 may be output based on the control of the fourth sub-word line decoder 453 of the left sub bank SBKL. The seventh data bit DQ6 of each of the bursts BL0 to BL15 may be output based on the control of the fourth sub-word line decoder 453 of the right sub bank SBKR. The eighth data bit DQ7 of each of the bursts BL0 to BL15 may be output based on the control of the fifth sub-word line decoder 454 of the right sub bank SBKR.

As illustrated in 920 of FIG. 9, the second data chunk corresponding to an address where the most significant bit RA15 of the row address RA is 1 may be configured of the first data bit DQ0 of each of the bursts BL0 to BL15, the second data bit DQ1 of each of the bursts BL0 to BL15, the third data bit DQ2 of each of the bursts BL0 to BL15, the fourth data bit DQ3 of each of the bursts BL0 to BL15, the fifth data bit DQ4 of each of the bursts BL0 to BL15, the sixth data bit DQ5 of each of the bursts BL0 to BL15, the seventh data bit DQ6 of each of the bursts BL0 to BL15, and the eighth data bit DQ7 of each of the bursts BL0 to BL15. The first data bit DQ0 of each of the bursts BL0 to BL15 may be output based on the control of the first sub-word line decoder 450 of the right sub bank SBKR. The second data bit DQ1 of each of the bursts BL0 to BL15 may be output based on the control of the second sub-word line decoder 451 of the right sub bank SBKR. The third data bit DQ2 of each of the bursts BL0 to BL15 may be output based on the control of the first sub-word line decoder 450 of the left sub bank SBKL. The fourth data bit DQ3 of each of the bursts BL0 to BL15 may be output based on the control of the second sub-word line decoder 451 of the left sub bank SBKL. The fifth data bit DQ4 of each of the bursts BL0 to BL15 may be output based on the control of the third sub-word line decoder 452 of the right sub bank SBKR. The sixth data bit DQ5 of each of the bursts BL0 to BL15 may be output based on the control of the fourth sub-word line decoder 453 of the right sub bank SBKR. The seventh data bit DQ6 of each of the bursts BL0 to BL15 may be output based on the control of the fourth sub-word line decoder 453 of the left sub bank SBKL. The eighth data bit DQ7 of each of the bursts BL0 to BL15 may be output based on the control of the fifth sub-word line decoder 454 of the left sub bank SBKL.

When the sub-word line decoder 450 that controls memory cells related to the first data bit DQ0 and the third data bit DQ2 fails as described above, an error may occur only in the data associated with the first data bit DQ0 in the first data chunk, and an error may occur only in the data associated with the third data bit DQ2 in the second data chunk. Accordingly, although the number of errors occurring in the entire data is the same, the number of errors occurring in each data chunk can be reduced by half.

Accordingly, data with an error occurred therein may be recovered using an error correction code. For example, the error correction code may be Reed-Solomon (RS) parity data. The Reed-Solomon error correction operation is a method of correcting errors in units of data chunks. According to the Reed-Solomon error correction operation, although a plurality of error bits is included in a data chunk, which is the unit of error correction, the data chunk with the error bits occurred therein can be corrected. In the Reed-Solomon error correction operation, the number of errors that can be corrected may be determined by the size of Reed-Solomon parity data.

Therefore, when the number of consecutively occurring errors is reduced by half as described above, the possibility of correction can be greatly increased for the same size of parity data.

In FIGS. 8 and 9, an embodiment of the present disclosure proposes a method of reducing the size of data controlled by each sub-word line decoder within one data chunk by half by simultaneously operating two sub-banks SBKL and SBKR provided in one bank and using the most significant bit RA15 of the row address RA.

In a second embodiment, the size of data controlled by each sub-word line decoder within one data chunk can be reduced to ¼ by simultaneously operating two banks provided in one bank group shown in FIG. 3 and using the least significant bit BA0 of the bank selection address and the most significant bit RA15 of the row address RA.

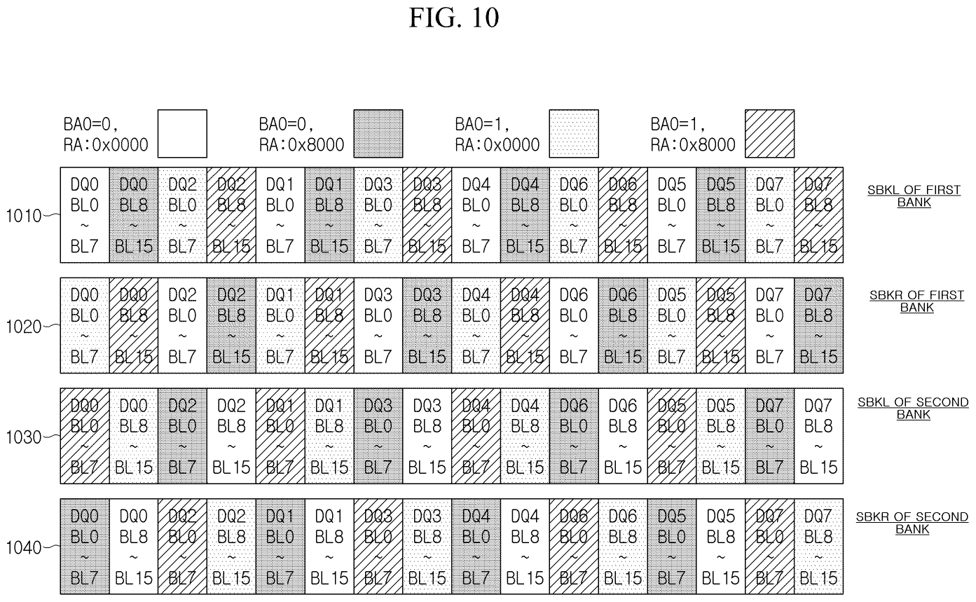

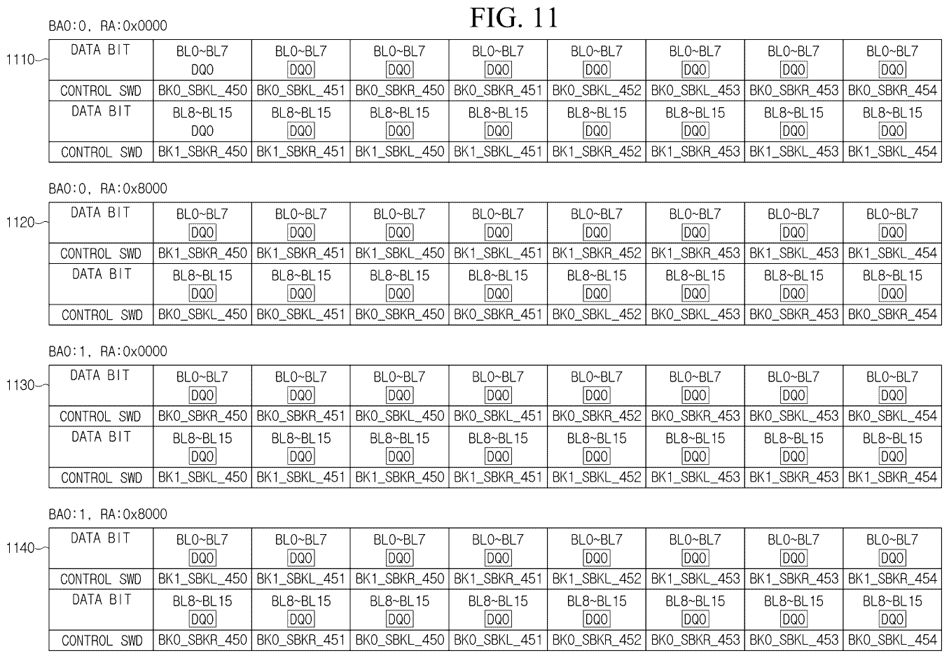

FIG. 10 is a view showing data stored in each memory cell according to a method proposed in a second embodiment of the present disclosure. FIG. 11 is a view showing an output result in the case of reading according to the method proposed in a second embodiment of the present disclosure.

Referring to FIG. 10, one data chunk may be stored to be distributed in two sub-banks SBKL and SBKR in two banks, i.e., four sub-banks.

The one type of method that has been proposed includes selecting a bank using a bank address BA, selecting one sub-bank among the left sub-bank SBKL and the right sub-bank SBKR in the bank using the most significant bit RA15 of the row address RA, and storing all data in a data chunk in the selected sub-bank or reading data from the selected sub-bank.

The structure according to a second embodiment may be changed to a structure in which all four sub-banks that can be selected by the least significant bit BA0 of the bank address and the most significant bit RA15 of the row address RA are activated, and each sub-word line decoder controls to activate only 8 memory cells among the controlled 32-bit memory cell.

According to an embodiment, when the least significant bit BA0 of the bank address is 0 and the most significant bit RA15 of the row address RA is 0, as shown in FIG. 10, 1) the sub-word line decoder of the left sub-bank SBKL of the first bank activates memory cells related to the first data bit DQ0, the second data bit DQ1, the fifth data bit DQ4, and the sixth data bit DQ5 of the first burst BL0 to the eighth burst BL7 (1010), 2) the sub-word line decoder of the right sub-bank SBKR of the first bank activates memory cells related to the third data bit DQ2, the fourth data bit DQ3, the seventh data bit DQ6, and the eighth data bit DQ7 of the first burst BL0 to the eighth burst BL7 (1020), 3) the sub-word line decoder of the left sub-bank SBKL of the second bank activates memory cells related to the third data bit DQ2, the fourth data bit DQ3, the seventh data bit DQ6, and the eighth data bit DQ7 of the ninth burst BL8 to the sixteenth burst BL15 (1030), and 4) the sub-word line decoder of the right sub-bank SBKR of the second bank activates memory cells related to the first data bit DQ0, the second data bit DQ1, the fifth data bit DQ4, and the sixth data bit DQ5 of the ninth burst BL8 to the sixteenth burst BL15 (1040).

When the least significant bit BA0 of the bank address is 0 and the most significant bit RA15 of the row address RA is 1, as shown in FIG. 10, 1) the sub-word line decoder of the left sub-bank SBKL of the first bank activates memory cells related to the first data bit DQ0, the second data bit DQ1, the fifth data bit DQ4, and the sixth data bit DQ5 of the nineth burst BL8 to the sixteenth burst BL15 (1010), 2) the sub-word line decoder of the right sub-bank SBKR of the first bank activates memory cells related to the third data bit DQ2, the fourth data bit DQ3, the seventh data bit DQ6, and the eighth data bit DQ7 of the nineth burst BL8 to the sixteenth burst BL15 (1020), 3) the sub-word line decoder of the left sub-bank SBKL of the second bank activates memory cells related to the third data bit DQ2, the fourth data bit DQ3, the seventh data bit DQ6, and the eighth data bit DQ7 of the first burst BL0 to the eighth burst BL7 (1030), and 4) the sub-word line decoder of the right sub-bank SBKR of the second bank activates memory cells related to the first data bit DQ0, the second data bit DQ1, the fifth data bit DQ4, and the sixth data bit DQ5 of the first burst BL0 to the eighth burst BL7 (1040).

Even when the least significant bit BA0 of the bank address is 1 and the most significant bit RA15 of the row address RA is 0, and the least significant bit BA0 of the bank address is 1 and the most significant bit RA15 of the row address RA is 1, each sub-word line decoder controls only one byte of data in each data chunk as shown in FIG. 10.

Accordingly, as shown in FIG. 11, the first data chunk (1110) corresponding to an address where the least significant bit BA0 of the bank address is 0 and the most significant bit RA15 of the row address RA is 0 may be configured of 1) the first data bit DQ0 of the first burst BL0 to the eighth burst BL7 output based on the control of the first sub-word line decoder 450 of the left sub-bank SBKL, 2) the second data bit DQ1 of the first burst BL0 to the eighth burst BL7 output based on the control of the second sub-word line decoder 451 of the left sub-bank SBKL, 3) the third data bit DQ2 of the first burst BL0 to the eighth burst BL7 output based on the control of the first sub-word line decoder 450 of the right sub-bank SBKR, 4) the fourth data bit DQ3 of the first burst BL0 to the eighth burst BL7 output based on the control of the second sub-word line decoder 451 of the right sub-bank SBKR, 5) the fifth data bit DQ4 of the first burst BL0 to the eighth burst BL7 output based on the control of the third sub-word line decoder 452 of the left sub-bank SBKL, 6) the sixth data bit DQ5 of the first burst BL0 to the eighth burst BL7 output based on the control of the fourth sub-word line decoder 453 of the left sub-bank SBKL, 7) the seventh data bit DQ6 of the first burst BL0 to the eighth burst BL7 output based on the control of the fourth sub-word line decoder 453 of the right sub-bank SBKR, and 8) the eighth data bit DQ7 of the first burst BL0 to the eighth burst BL7 output based on the control of the fifth sub-word line decoder 454 of the right sub-bank SBKR.

The second data chunk (1120) corresponding to an address where the least significant bit BA0 of the bank address is 0 and the most significant bit RA15 of the row address RA is 1 may be configured of 1) the first data bit DQ0 of the ninth burst BL8 to the sixteenth burst BL15 output based on the control of the first sub-word line decoder 450 of the right sub-bank SBKR, 2) the second data bit DQ1 of the ninth burst BL8 to the sixteenth burst BL15 output based on the control of the second sub-word line decoder 451 of the right sub-bank SBKR, 3) the third data bit DQ2 of the ninth burst BL8 to the sixteenth burst BL15 output based on the control of the first sub-word line decoder 450 of the left sub-bank SBKL, 4) the fourth data bit DQ3 of the ninth burst BL8 to the sixteenth burst BL15 output based on the control of the second sub-word line decoder 451 of the left sub-bank SBKL, 5) the fifth data bit DQ4 of the ninth burst BL8 to the sixteenth burst BL15 output based on the control of the third sub-word line decoder 452 of the right sub-bank SBKR, 6) the sixth data bit DQ5 of the ninth burst BL8 to the sixteenth burst BL15 output based on the control of the fourth sub-word line decoder 453 of the right sub-bank SBKR, 7) the seventh data bit DQ6 of the ninth burst BL8 to the sixteenth burst BL15 output based on the control of the fourth sub-word line decoder 453 of the left sub-bank SBKL, and 8) the eighth data bit DQ7 of the ninth burst BL8 to the sixteenth burst BL15 output based on the control of the fifth sub-word line decoder 454 of the left sub-bank SBKL.

The third data chunk (1130) corresponding to an address where the least significant bit BA0 of the bank address is 1 and the most significant bit RA15 of the row address RA is 0 and the fourth data chunk (1140) corresponding to an address where the least significant bit BA0 of the bank address is 1 and the most significant bit RA15 of the row address RA is 1 may also be configured of sixteen 8-bit bursts output based on the control of all 16 sub-word line decoders as shown in FIG. 11.

Based on the control operation of the sub-word line drivers according to a second embodiment described above, when one sub-word line driver fails, errors may occur in only 8 bits in each of four different data chunks. Accordingly, although the number of errors occurring in the entire data is 32 bits, which is the same as that of the one type of method that has been proposed, the number of errors occurring in each data chunk may be reduced to ¼.

Accordingly, the possibility of recovering data with errors occurring therein can be greatly increased by using an error correction code.

In a third embodiment, the size of data controlled by each sub-word line decoder within one data chunk can be reduced to one-eighth (⅛) by simultaneously operating four banks provided in one bank group shown in FIG. 3 and using the most significant bits RA15 of the bank selection addresses BA1 and BA0 and the most significant bit RA15 of the row address RA. Although detailed description thereof is omitted, it can be similarly inferred based on FIGS. 10 and 11.

The operation of the memory device described based on the embodiments described above may be summarized as follows.

The memory device may include a plurality of bank groups, each bank group including a plurality of banks, and a peripheral circuit configured to receive a control signal and a data chunk from an external device, and store the data chunk to be distributed in at least two or more sub-banks selected from among the plurality of bank groups.

In order to store the data chunk to be distributed in two sub-banks in the bank selected based on the control signal, the memory device may further include a plurality of sub-word line drivers for controlling the memory cells. The control signal includes a bank group address for selecting one bank group among the plurality of bank groups, a bank address for selecting one bank among the plurality of banks in the selected bank group, a row address for selecting a word line for storing the data chunk in the selected bank, and a column address for selecting memory cells for storing the data chunk among memory cells associated with the selected word line. The peripheral circuit is configured to select a first bank for storing the data chunk based on the bank group address and the bank address, and select a first word line for storing the data chunk in each of two sub-banks in the first bank based on the remaining bits excluding the most significant bit of the row address. The peripheral circuit selects first memory cells for storing data among the memory cells associated with the first word line based on the column address in each of the two sub-banks. The first sub-word line drivers connected to the first word line of the first sub-bank among the two sub-banks in the first bank may be configured to control the first memory cells of the first sub-bank so that some data of the data chunk may be stored based on the most significant bit of the row address. The second sub-word line drivers connected to the first word line of the second sub-bank among the two sub-banks in the first bank may be configured to control the first memory cells of the first sub-bank so that remaining data of the data chunk may be stored based on the most significant bit of the row address.

When the most significant bit of the row address is 0, the first sub-word line drivers may control to store four data bits among eight data bits of N bursts of the data chunk (a total of 4N first data bits) in some of the first memory cells of the first sub-bank, and the second sub-word line drivers may control to store remaining four data bits among eight data bits of N bursts of the data chunk (a total of 4N second data bits) in some of the first memory cells of the second sub-bank.

When the most significant bit of the row address is 1, the first sub-word line drivers may control to store a total of 4N second data bits in the remaining first memory cells of the first sub-bank, and the second sub-word line drivers may control to store a total of 4N first data bits in the remaining first memory cells of the second sub-bank.

The peripheral circuit may be configured to store the data chunk to be distributed in four sub-banks in the two banks selected based on the control signal.

The memory device further includes a plurality of sub-word line drivers for controlling the memory cells.

The control signal includes a bank group address for selecting one among the plurality of bank groups, a bank address for selecting one among the plurality of banks in the selected bank group, a row address for selecting a word line for storing the data chunk in the selected bank, and a column address for selecting memory cells for storing the data chunk among memory cells associated with the selected word line.

The peripheral circuit is configured to select a first bank and a second bank for storing the data chunk based on remaining bits excluding the least significant bits of the bank group address and the bank address, and select a first word line for storing the data chunk in each of two sub-banks in the first bank and two sub-banks in the second bank based on the remaining bits excluding the most significant bit of the row address.

The peripheral circuit selects first memory cells for storing data among the memory cells associated with the first word line based on the column address in each of the four sub-banks.

The first sub-word line drivers connected to the first word line of the first sub-bank among the two sub-banks in the first bank may be configured to control the first memory cells of the first sub-bank in the first bank so that some data of the data chunk may be stored based on the least significant bit of the bank address and the most significant bit of the row address.

The second sub-word line drivers connected to the first word line of the second sub-bank among the two sub-banks in the first bank may be configured to control the first memory cells of the second sub-bank in the first bank so that some data of the data chunk may be stored based on the least significant bit of the bank address and the most significant bit of the row address.

The third sub-word line drivers connected to the first word line of the first sub-bank among the two sub-banks in the second bank may be configured to control the first memory cells of the first sub-bank in the second bank so that some data of the data chunk may be stored based on the least significant bit of the bank address and the most significant bit of the row address.

The fourth sub-word line drivers connected to the first word line of the second sub-bank among the two sub-banks in the second bank may be configured to control the first memory cells of the second sub-bank in the second bank so that some data of the data chunk may be stored based on the least significant bit of the bank address and the most significant bit of the row address.

When the least significant bit of the bank address is 0 and the most significant bit of the row address is 0, the first sub-word line drivers may control to store two data bits among eight data bits of N bursts of the data chunk (a total of 2N first data bits) in some of the first memory cells of the first sub-bank of the first bank, the second sub-word line drivers may control to store two data bits among eight data bits of N bursts of the data chunk (a total of 2N second data bits) in some of the first memory cells of the second sub-bank of the first bank, the third sub-word line drivers may control to store two data bits among eight data bits of N bursts of the data chunk (a total of 2N third data bits) in some of the first memory cells of the first sub-bank of the second bank, and the fourth sub-word line drivers may control to store the remaining two data bits among eight data bits of N bursts of the data chunk (a total of 2N fourth data bits) in some of the first memory cells of the second sub-bank of the second bank.

As described above, as the method proposed in the present disclosure reduces the number of bits controlled by each sub-word line driver in one data chunk by storing data included in one data chunk to be distributed in a plurality of sub-banks, rather than storing all data in one sub-bank, the possibility of recovering the data chunk can be increased even when one sub-word line driver fails, by reducing the number of consecutive error bits occurring in one data chunk.

The memory device proposed in the present disclosure may increase the possibility of recovering errors in a data chunk using an error correction code by reducing the number of error bits that may occur due to burst defects.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure. Furthermore, the embodiments may be combined to form additional embodiments.

What is claimed is:

1. A memory device comprising:
a plurality of bank groups, each bank group including a plurality of banks, each bank including two sub-banks, each sub-bank including a plurality of memory cells; and
a peripheral circuit configured to receive a first control signal and a data chunk from an external device, and store the data chunk to be distributed in at least two or more sub-banks selected from among sub-banks included in the plurality of bank groups.

2. The memory device according to claim 1, wherein the peripheral circuit is configured to select one bank from among banks of the plurality of bank groups, based on the first control signal, and store the data chunk to be distributed in two sub-banks in the selected bank.

3. The memory device according to claim 2, wherein the first control signal comprises a first address, and
wherein the peripheral circuit is further configured to:
select a first bank based on a part of the first address, and
store a half of the data chunk in each of the two sub-banks of the selected first bank, based on a remaining part of the first address.

4. The memory device according to claim 2, wherein the peripheral circuit is further configured to receive a second control signal from the external device, and read the data chunk stored from two sub-banks in the selected bank based on the second control signal.

5. The memory device according to claim 1, wherein the peripheral circuit is configured to select two banks from among banks of the plurality of bank groups, based on the first control signal, and store the data chunk to be distributed in four sub-banks in the selected two banks.

6. The memory device according to claim 5, wherein the selected two banks are included in the same bank group.

7. The memory device according to claim 6, wherein the first control signal comprises a second address, and
wherein the peripheral circuit is further configured to:
select a first bank group based on a first part of the second address,
select a first bank and a second bank among the plurality of banks in the first bank group based on a second part of the second address, and
store a quarter of the data chunk in each of two sub-banks of the first bank and two sub-banks of the second bank based on a remaining part of the second address.

8. The memory device according to claim 1, wherein the peripheral circuit is configured to select one bank group among the plurality of bank groups based on the first control signal, and store the data chunk to be distributed in eight sub-banks in four banks in the selected bank group.

9. The memory device according to claim 8, wherein the first control signal comprises a third address, and
wherein the peripheral circuit is configured to:
select a first bank group based on a first part of the third address,
store one-eighth of the data chunk in each of two sub-banks in four banks in the first bank group based on a second part of the third address.

10. A data storage device comprising:
a plurality of first memory devices for storing a data chunk;
a second memory device for storing an error correction code generated based on the data chunk; and
a peripheral circuit configured to receive a first control signal from an external device and control the plurality of first memory devices and the second memory device,
wherein each of the plurality of first memory devices and the second memory device comprises:
a plurality of bank groups, each bank group including a plurality of banks, each bank including two sub-banks, each sub-bank including a plurality of memory cells, and
wherein the peripheral circuit is configured to store the data chunk and the error correction code to be distributed in at least two or more sub-banks selected from among sub-banks included in the plurality of bank groups in each of the plurality of first memory devices and the second memory device.

11. The data storage device according to claim 10, wherein the peripheral circuit is further configured to select one bank from among banks of the plurality of bank groups in each of the plurality of first memory devices and the second memory device, based on the first control signal, and store the data chunk and the error correction code to be distributed in two sub-banks in the selected bank.

12. The data storage device according to claim 11, wherein the first control signal comprises a first address, and
wherein the peripheral circuit is further configured to:
select a first bank from each of the plurality of first memory devices and the second memory device based on a part of the first address, and
store the data chunk and the error correction code in two sub-banks of the selected first bank, based on a remaining part of the first address.

13. The data storage device according to claim 11, wherein the peripheral circuit is further configured to:
receive a second control signal from the external device, and
read the data chunk and the error correction code stored from two sub-banks in the selected bank based on the second control signal.

14. The data storage device according to claim 10, wherein the peripheral circuit is further configured to:
select two banks from among banks of the plurality of bank groups in each of the plurality of first memory devices and the second memory device based on the first control signal, and
store the data chunk and the error correction code to be distributed in four sub-banks in the selected two banks.

15. The data storage device according to claim 10, wherein the peripheral circuit is further configured to:
select one bank group among the plurality of bank groups from each of the plurality of first memory devices and the second memory device based on the first control signal, and
store the data chunk and the error correction code to be distributed in eight sub-banks of four banks in the selected bank group.

16. The data storage device according to claim 10, wherein the number of the plurality of first memory devices is 4.

17. The data storage device according to claim 16, wherein a size of the data chunk is calculated by multiplying a burst length (N) and 32 bits, and a size of the error correction code is calculated by multiplying a burst length (N) and 8 bits.

18. The data storage device according to claim 17, wherein each of the plurality of first memory devices and the second memory device is configured to simultaneously receive or output eight bits.

19. The data storage device according to claim 18, wherein the peripheral circuit sequentially receives 40-bit data signals from the external device for as many times as a number corresponding to the burst length.

20. The data storage device according to claim 19, wherein the peripheral circuit sequentially transfers 8 bits at a time to each of the plurality of first memory devices and the second memory device.
